(19) United States
(12) Patent Application Publication
(10) Pub. No.: US 2026/0302123 A1
(43) Pub. Date: Oct. 1, 2026

(54) Multi-Mode Radio Frequency Cavity

(71) Applicant: Board of Trustees of Michigan State University, East Lansing, MI (US)

(72) Inventors: Benjamin Geoffrey SIMS, Sante Fe, NM (US); Sergey V. BARYSHEV, Okemos, MI (US)

(73) Assignee: Board of Trustees of Michigan State University, East Lansing, MI (US)

(21) Appl. No.: 19/629,785

(22) Filed: Mar. 26, 2026

Related U.S. Application Data
(60) Provisional application No. 63/781,467, filed on Apr. 1, 2025.

(51) Int. Cl. H01J 37/065; H01J 37/04; H01J 37/26

(52) U.S. Cl. CPC H01J 37/065; H01J 37/045; H01J 37/265

(57) ABSTRACT

A multi-mode radio frequency cavity provides both an electric field and a magnetic field therein. Another aspect provides an apparatus including a radio frequency gun, at least one radio frequency power supply and a dual-mode electron bunching cavity. In another aspect, a radio frequency cavity includes both an on-axis/on-equator tuner and an off-axis/off-equator tuner. A method of using a radio frequency cavity with a radio frequency cavity with both on-axis/on-equator cavity tuning and an off-axis/off-equator cavity tuning, is provided in yet another aspect.

### CROSS-REFERENCE TO RELATED APPLICATION

This application claims priority to provisional patent application Ser. No. 63/781,467, filed on Apr. 1, 2025, which is incorporated by reference herein.

### GOVERNMENT SUPPORT

This invention was made with government support under DE-SC0018362 awarded by the U.S. Department of Energy. The government has certain rights in the invention.

### BACKGROUND AND SUMMARY

The present disclosure relates generally to electron spectroscopy and more particularly to an electron spectroscopy system including a radio frequency cavity and multiple spectrometers.

Electron microscopes are known which employ a radio frequency photogun, an electron beam column, and a bunching radio frequency cavity. Such traditional devices are often used for scanning electron microscopy (“SEM”), transmission electron microscopy (“TEM”), horizontal/vertical accelerator-based beamlines, and the like. For example, a radio frequency powered and tunable transverse deflecting cavity is disclosed in U.S. Patent Publication No. 2016/0293377 entitled “Apparatus for GHz Rate High Duty Cycle Pulsing and Manipulation of Low and Medium Energy DC Electron Beams” which published to common inventor Baryshev on Oct. 6, 2016. This patent publication is incorporated by reference herein.

It is noteworthy that some known devices that use a higher-order mode, radio frequency cavity disadvantageously require high radio frequency power. Such a traditional system is disclosed in Lewellen, J., “Higher-Order Mode RF Guns,” Phys. Rev. STAB, Vol. 4, p. 040101 (2001).

In accordance with the present invention, a multi-mode radio frequency cavity provides both an electric field and a magnetic field therein. Another aspect provides an apparatus including a radio frequency gun, at least one radio frequency power supply and a dual-mode electron bunching cavity. In another aspect, a radio frequency cavity includes both an on-axis/on-equator tuner and an off-axis/off-equator tuner. A further aspect of the present system employs an electron gun, a radio frequency cavity, a fundamental mode or magnetic field loop coupler in the cavity, plus a harmonic mode or electric field coupler/probe in the cavity. A method of using a radio frequency cavity having a fundamental mode/magnetic field and a harmonic mode/electric field is provided in another aspect. Moreover, a method of using a radio frequency cavity with a radio frequency cavity with both on-axis/on-equator cavity tuning and an off-axis/off-equator cavity tuning, is provided in yet another aspect.

The present multi-mode radio frequency cavity apparatus and method advantageously allow for individually controlling the amplitude and phase of each mode with the fundamental mode excited via a short-circuit loop coupler which couples to the magnetic field, and the higher mode (harmonic) being coupled via an open-circuit straight wire coupler which couples to the electric field. By placing each coupler at a location where its specific mode had a high field and the other mode had a low field, the transmitted power between each coupler is minimized thereby allowing for maximal power delivered to the cavity volume (i.e. at minimal reflection of each mode and mode cross-coupling). Furthermore, crosstalk is minimized with the present cavity due to the use of two different couplers as well as off equator positioning to further minimize any transmitted power.

Additionally, the present cavity is substantially different from typical RF cavities used in particle accelerators in its versatility, efficiency and tunability. For example, the present cavity is configured to combine two modes via superposition of the electric and magnetic fields allowing for precise manipulation of the fields for multiple use cases. Also, the present cavity is configured to utilize unique coupler placement criteria to minimize transmitted power between the couplers and maximize the power transmitted to the cavity itself. And the present cavity is configured to beneficially produce a wide tuning range, where a large range of resonant frequencies are available to both modes. This allows for increased syncing between the modes as deviation from integer multiples of the frequencies will result in unintended fields. Additional advantages and features can be found in the following description and appended drawings.

### BRIEF DESCRIPTION OF THE DRAWINGS

FIG. 1 is a diagrammatic view showing the present multi-mode radio frequency cavity in an apparatus including an RF electron injector gun;

FIG. 2 is a diagrammatic view showing the present multi-mode radio frequency cavity in an apparatus including a DC electron injector gun;

FIG. 3 is a perspective view showing the present multi-mode radio frequency cavity with an electric field probe;

FIG. 4 is a perspective view showing the present multi-mode radio frequency cavity with a loop coupler;

FIG. 5 is a perspective view showing a housing of the present multi-mode radio frequency cavity;

FIG. 6 is a fragmentary and enlarged perspective view showing the loop coupler in present multi-mode radio frequency cavity;

FIG. 7 is a perspective view showing the loop coupler;

FIG. 8 is a diagrammatic view showing a fundamental mode, electric field map in present multi-mode radio frequency cavity;

FIG. 9 is a fragmentary and enlarged perspective view showing the electric field probe in present multi-mode radio frequency cavity;

FIG. 10 is a perspective view showing the electric field probe;

FIG. 11 is a diagrammatic view showing a harmonic mode, electric field map in present multi-mode radio frequency cavity;

FIG. 12 is a graph showing expected cross-talk from the loop coupler to the electric field probe of present multi-mode radio frequency cavity;

FIG. 13 is a graph showing expected cross-talk from the electric field probe to the loop coupler of present multi-mode radio frequency cavity;

FIG. 14 is a graph showing bunch compression of present multi-mode radio frequency cavity;

FIG. 15 is an enlarged cross-sectional view showing an optional tuner adjustment configuration employed in the present multi-mode radio frequency cavity;

FIG. 16 is fragmentary cross-sectional views showing on-equator effects of the optional tuner adjustment configuration employed in the present multi-mode radio frequency cavity;

FIG. 17 is fragmentary cross-sectional views showing off-equator effects of the optional tuner adjustment configuration employed in the present multi-mode radio frequency cavity;

FIGS. 18 and 19 are graphs showing frequency response from the on-equator tuner employed in the present multi-mode radio frequency cavity; and

FIGS. 20 and 21 are graphs showing frequency response from the off-equator tuner employed in the present multi-mode radio frequency cavity.

### DETAILED DESCRIPTION

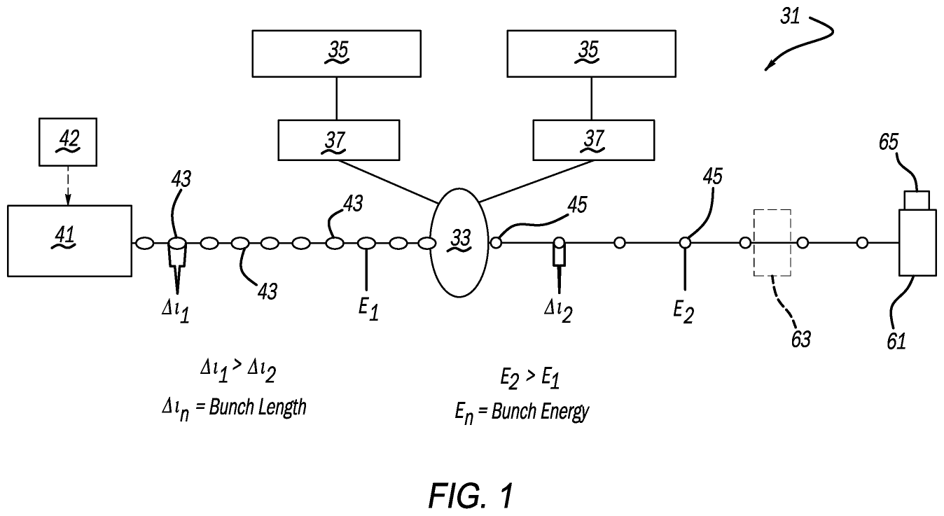

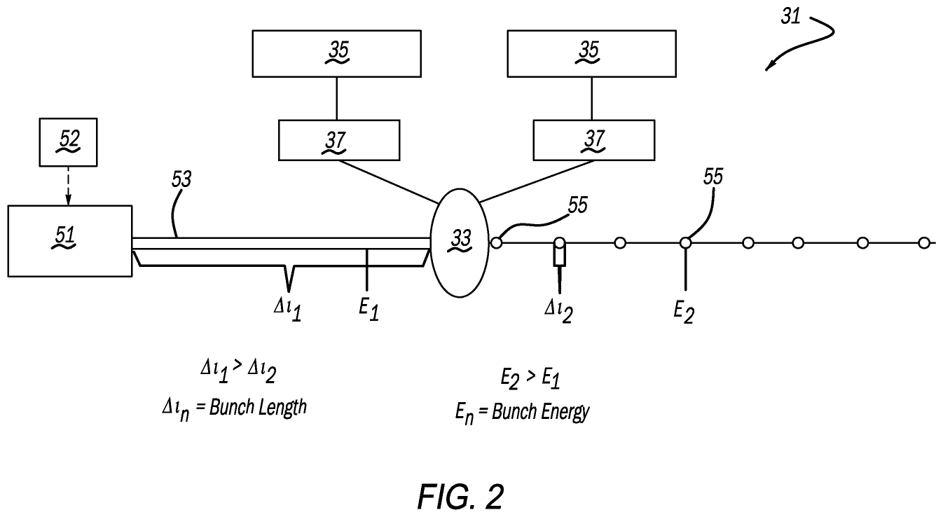

A radio frequency (“RF”) electron accelerator apparatus 31 employs an energy-compression, dual-mode radio frequency cavity 33 which is coupled to two sets of RF generators or power supplies 35 and RF amplifiers 37, as can be observed in FIG. 1. A first embodiment of apparatus 31 is illustrated in FIG. 1 and includes an electron injector, RF photoelectron gun 41, which is driven by a laser 42. RF gun 41 emits a series of electron bunches 43 in each pulse or shot. Referring to FIG. 2, a second embodiment of apparatus 31 includes an electron injector, direct current (“DC”) photoelectron gun 51, which is driven by a laser 52. DC gun 51 emits a continuous pulse or shot with an electron bunch 53 therein. The bunch length Δt₁ of each electron beam bunch 53 entering RF cavity 33, associated with the DC gun, is greater than for the bunch length of each entering electron beam bunch 43 associated with the RF gun. Electron energy E₂ of each bunch 45 (FIG. 1) and 55 (FIG. 2) exiting RF cavity 33 is greater than the electron energy E₁ of each bunch 43 (FIG. 1) and 53 (FIG. 2) entering RF cavity 33.

RF photoinjector gun 41 serves to generate high quality electron beams for high-brilliance hard X-ray production for free-electron laser and time-resolved microscopy use. Typically, particles gain energy by undergoing acceleration due to an electric field inside an accelerating cavity. The brilliance is highest when the greatest charge can be contained in the smallest phase space volume.

Emittance is a measurement of the phase space area of a particle bunch. Furthermore, three of the main contributors to emittance are space charge emittance, RF emittance and intrinsic emittance. Space charge emittance is due to the Coulombic interactions between electrons which push the bunch over time as all of the particles are the same charge and repel each other. RF emittance is due to the diverging field effects seen as the particles deviate from the on-axis field inside of the RF cavity. The stronger the RF field and the larger the bunch, the worse the RF emittance contribution becomes. They typically create conflicting parameters between space charge, which desires a large bunch and high field, and RF emittance is lowest with a small bunch and low field.

In one exemplary configuration, apparatus 31 employs the dual-cavity bunched electrons 45 or 55 to generate an image of a target specimen 61 for spectroscopy in a vacuum chamber. In another configuration with free electron laser 42, bunched electrons 45 or 55 are converted to X-rays by an optional undulator 63 and only then these X-rays go to the target specimen or workpiece 61, imaged by an optional CCD camera 65 or other photodetector. Increased brightness of the electron beam correlates to a tighter and more intense X-ray bunch produced which increases the resolution on targe as well as requiring less beam time to achieve results.

A further configuration employs apparatus 31 with an ultra-fast electron diffraction process that uses the electron beams to directly image a target material specimen. Alternately, another configuration converts electron energy bunches 45 or 55 to high power terahertz signals and then sends them onto a target specimen or workpiece. Still another end use of the present apparatus 31 uses a superconducting version of RF cavity 33, operating in a GHz range, to create and manipulate long-lived quantum states or a quantum bit for quantum computing. Yet another configuration uses apparatus 31 with dual-mode RF cavity 33 to simultaneously accelerate and shape electrons in a Linac system.

The present dual-mode RF cavity 33 advantageously achieves a novel electromagnetic structure which is compact, efficient, has reduced cost (for example, one cavity versus conventionally two), and is synergistically multifunctional. The cavity beneficially balances the dual-mode structure considering mode frequencies, quality factor (“Q-factor”), and minimizes cross-talk between couplers. A combination of a fundamental mode TM₀₁₀ and a TM₀₁₁ mode, tuned to a harmonic of the fundamental, is realized to linearize an off-crest electric field, thereby enabling concurrent bunching and acceleration of charged particle (such as electron) beam in high power systems. The reduction in the quantity of cavities required to bunch and accelerate provides cost and space savings over conventional approaches.

The present RF cavity 33 is a dual-mode TM₀₁₀/TM₀₁₁, S/C-band (2.81/5.62 GHZ) cavity. By using a second harmonic to linearize the time-dependence of a field experienced by a particle transiting the cavity, it can serve to both accelerate and chirp a beam for velocity-based bunch compression, while reducing or eliminating the intra-cavity beam energy droop typically associated with the operation of a standard “buncher” cavity.

A buncher capable of supporting multiple TM modes breaks the conventional tradeoff between deceleration and nonlinear chirping. Instead of synchronizing the particle bunches with the zero crossings of the RF field, the present cavity modes are adjusted in phase and amplitude such that the incoming beam is accelerated, yet remains on a highly linear portion of the RF waveform. The result is a reduction (or elimination) of the beam deceleration while transiting the cavity; a net energy gain; and a highly linear chirp. Multi-mode bunching with the present apparatus can thereby mitigate the potential for emittance degradation due to deceleration while also allowing for a stronger chirp to be applied to a lower-energy incoming beam, all else being equal, while maintaining a high degree of linearity in the applied chirp.

A first step in designing the TM₀₁₀/TM₀₁₁ cavity 33 is estimating an optimal length for both modes to coexist in a cylindrical pillbox cavity with an integer ratio between their mode frequencies, using the following equation (1):

$$f ( {L}_{cav} , {R}_{cav} , p , m , n ) = \frac{c}{2 π} \sqrt{{( \frac{{x}_{p , m}}{{R}_{cav}} )}^{2} + {( \frac{n π}{{L}_{cav}} )}^{2}} \qquad ( 1 )$$

The fundamental axial mode corresponds to the TM₀₁₀ mode with longitudinal and radial electric fields and a transverse (azimuthal) magnetic field. A similar field arrangement holds for the TM₀₁₁, except that this mode's on-axis electric field reverses direction at the midpoint of the cavity.

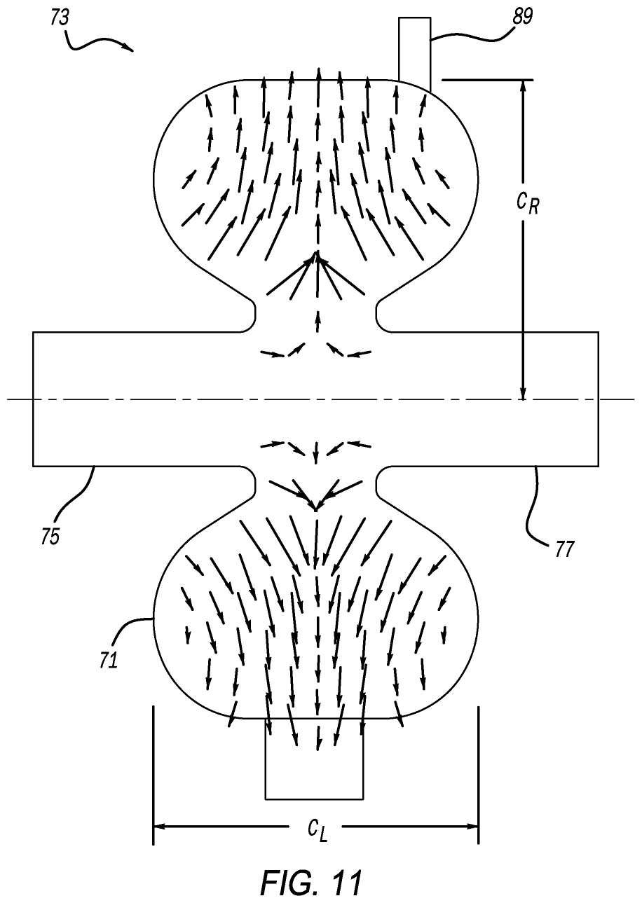

Referring to FIGS. 8 and 11, since the frequency of the fundamental mode depends only on the radius CR (e.g., n=0) of RF cavity 33, while the TM₀₁₁ mode depends on both the cavity radius and length CL (e.g., n=1), the cavity can be designed to support both modes at specific frequencies. By way of non-limiting example, the present RF cavity 33 is designed to resonate at 2.81 GHz (TM₀₁₀) and 5.62 GHZ (TM₀₁₁), which provides an integer ratio of 2 between the fundamental and harmonic frequencies. The frequency choice is driven by two factors. First, it is in the technologically desirable S/C-band regime for compact and high gradient cavities. Second, it benefits from high-power, solid state GaN amplifier technology to demonstrate beyond-klystron operation.

The cavity shape is generally of a re-entrant design with the intent of increasing the cavity shunt impedance for more efficient RF power use, and to provide a high gradient, high efficiency cavity design using an optimizer and sequencer. The cavity is tuned to account for the addition of tuner and RF power coupler ports. Design of the RF cavity accounts for each mode having its own independent coupler.

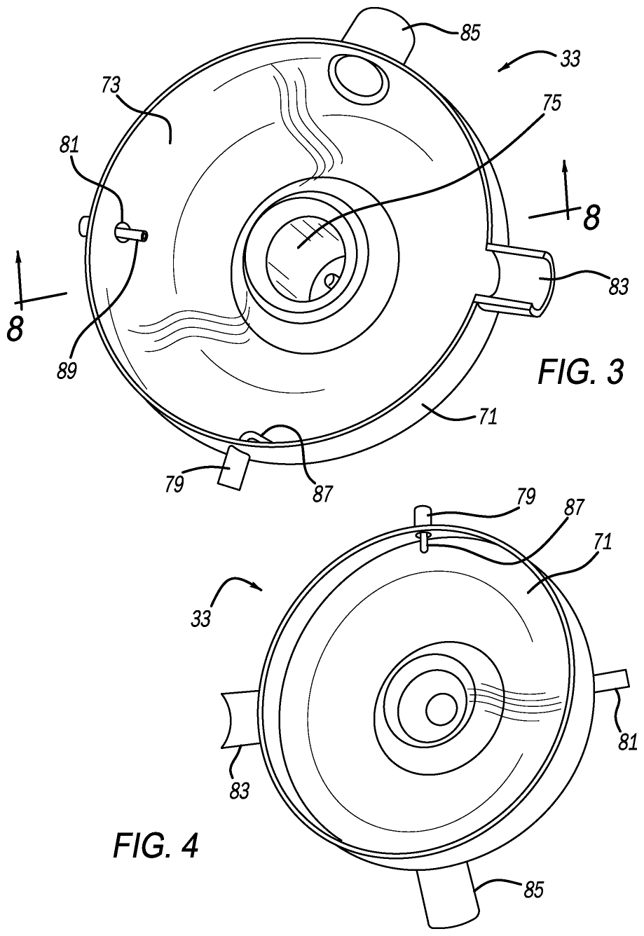

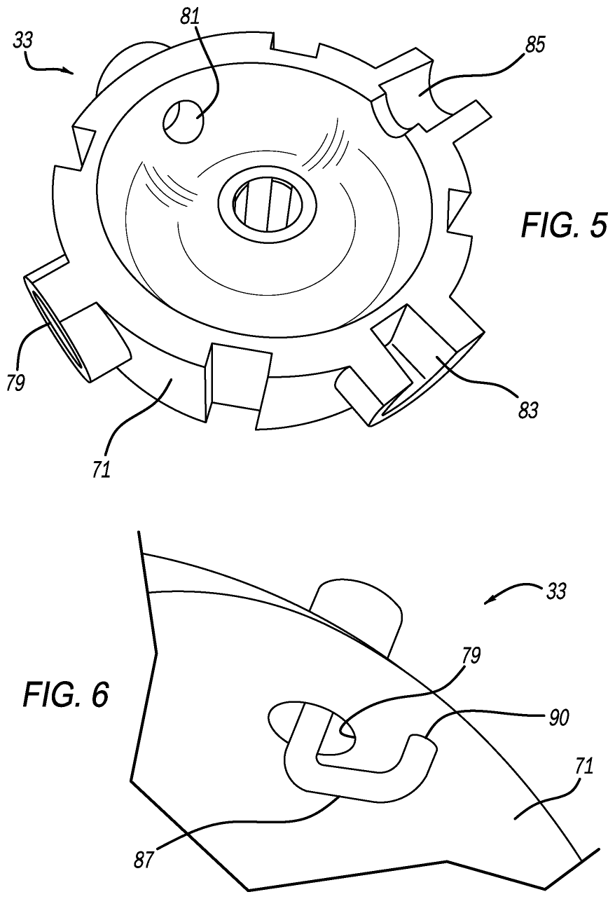

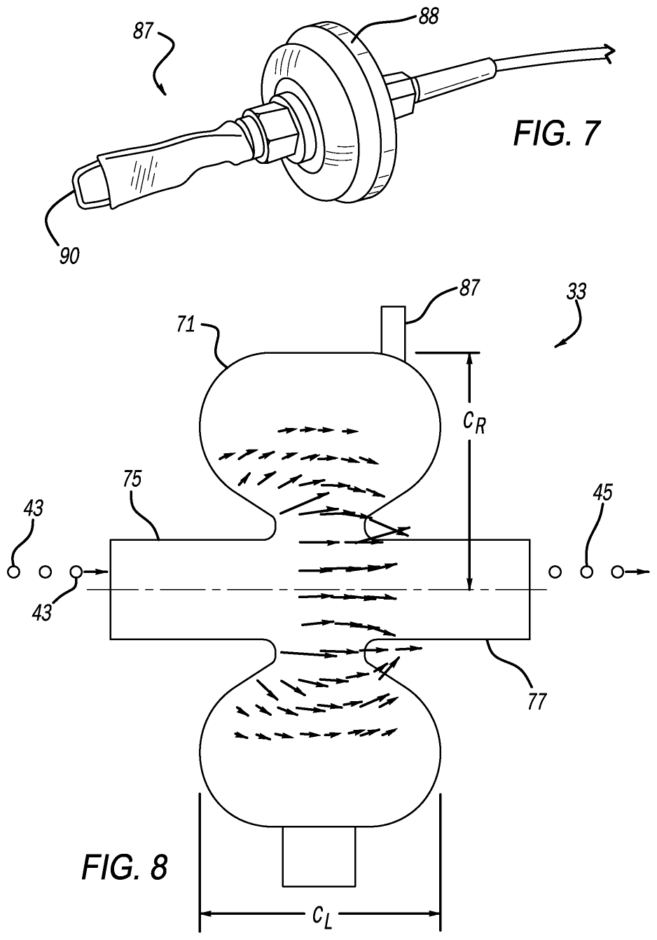

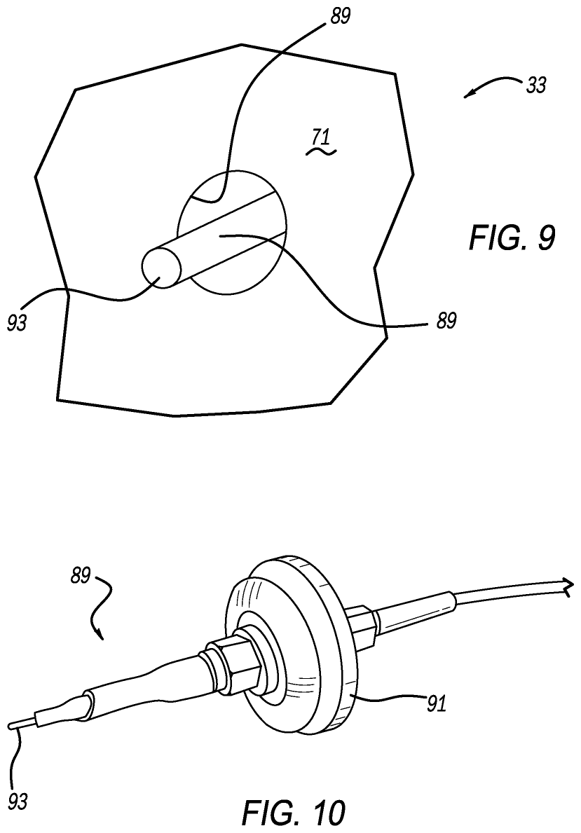

More specifically, with reference to FIGS. 3-11, an exemplary configuration of RF cavity 33 includes a generally round and hollow body 71 with a curved interior surface 73 therein. Cavity 33 may be cast and/or machined as multiple parts which are then welded or otherwise attached. A beam pipe leads to an electron entry port 75 configured to allow electrons 43 to enter into body 71, while an oppositely positioned electron exit port 77 is configured to allow electrons 45 to exit the body. Also present are a loop coupler port 79, an electric field probe port 81, an off-axis tuner port 83 and an on-axis tuner port 85, all entering generally circumferential outside edge of body 71.

RF cavity 33 includes an magnetic field loop coupler or probe 87 having a sealed collar 88 attached to body 71 with a hook-like or looped distal end segment 90 thereof located within the hollow interior of the body. In one exemplary configuration, a radial length of an initial section of segment 90 (which projects through port 79) is at least 0.2 cm extending beyond inner surface 73, a lateral middle section of segment 90 has a length of at least 0.4 cm, and a reverse section closest to the end of segment 90 is approximately the same as the initial section which is about half the length of the lateral middle section. RF cavity 33 further includes an electric field coupler or probe 89 having a sealed collar 91 attached to body 71 with a generally straight distal end segment 93 located within the hollow interior of the body. In one exemplary configuration, segment 93 extends into body 71 by at least 0.3 cm and more preferably 0.37 cm. Couplers 87 and 89 are spaced apart from each other but an offset angle of at least 30° and a majority of each coupler is radially aligned through the associated port 79 and 81, respectively, directed toward a center-point of body 71. Alternate dimensions and angle may be employed. At least one radio frequency generator 37 (see FIG. 1) is connected to the couplers, more preferably one RF generator for each coupler, and the couplers advantageously provide both an electric field and a magnetic field within the same cavity 33.

RF cavity 33 has a separate coupler for each mode, which facilitates independent control of each mode's phase and amplitude. Moreover, each coupler 87 and 89 is placed so that it primarily interacts with only one mode. The fundamental mode is excited via loop coupling 87 situated to couple strongly to the fundamental mode's magnetic field, and the present orientation optimizes minimal net coupling to the TM₀₁₁ mode. As the mode's (radial) electric field exhibits a relatively high amplitude at the cavity outer radius near the cavity equator, where the TM₀₁₀ mode field has a vanishing electric field along all directions in that region (see FIG. 11), electric field probe 89 is an effective method to couple exclusively to the TM₀₁₁ mode. Its location is also optimized to account for the specifics of the cavity modes' field distributions.

Avoiding locations of maximum field produced by each mode, and instead balancing all field at a given location, minimize cross-talk between the couplers 87 and 89. This is very desirable in the present two coupler system as strong cross-talk can be detrimental to system performance. Otherwise, couplers with significant cross-talk would both lower the overall cavity efficiency, in terms of RF power required to obtain a given accelerating gradient, due to undesired power out coupling, but also necessitate the RF network having a highly robust and effective, harmonic RF isolation system between the cavity and RF power sources.

FIG. 8 illustrates an electric field map within RF cavity 33 due to loop coupler 87, coupled via a magnetic field and in a fundamental mode TM₀₁₀ at an exemplary frequency of 2.81 GHZ. Figure illustrates an electrical field map within RF cavity 33 due to electric field probe coupler 89, coupled via an electric field and in a harmonic mode TM₀₁₁ at an exemplary frequency of 5.62 GHz. The small arrows within the RF cavity of FIG. 8 indicate a rotating magnetic field direction, a majority of which are generally aligned with the electron bunch entry and exit directions. The small arrows within the RF cavity of FIG. 11 indicate electric field direction, a majority of which are generally radially oriented and perpendicular to the electron bunch entry and exit directions.

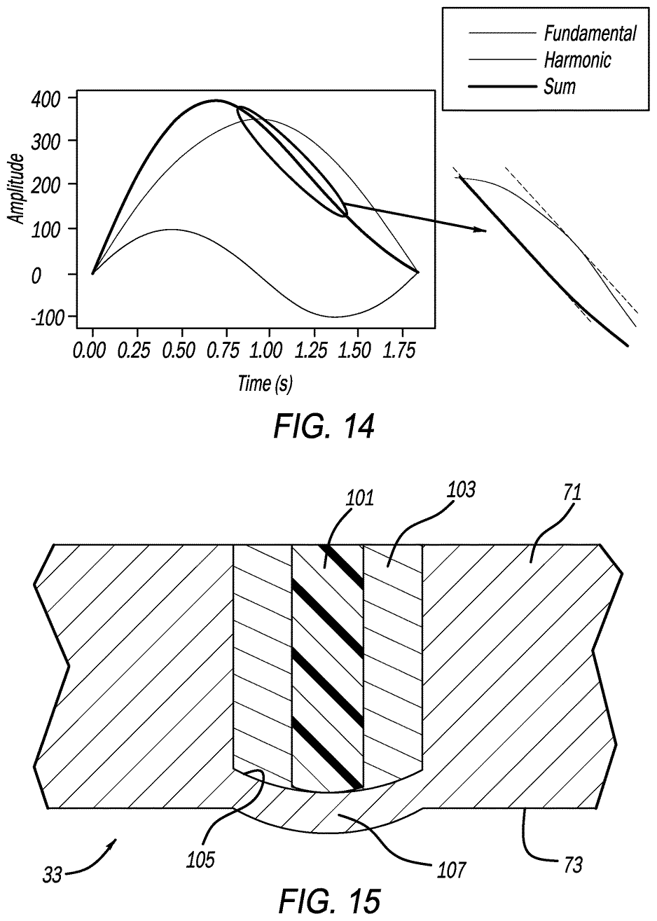

FIG. 14 illustrates expected results of bunch compression with the present dual-mode RF cavity. Mode interactions are shown for a fundamental mode, a harmonic mode and summation thereof. The advantageous results at the circled slope thereof, after the intersection of the fundamental mode and sum lines, are notable. In summary, bunch manipulation can improve brightness since bunch compression increases current and thus brightness. The bunch compression via the zero crossing is net zero energy gain, however, there is a portion of time where the bunch is slowed down and this can increase the emittance of the bunch, as space charge emittance increases at lower energies. Accordingly, the present dual-mode cavity accelerates and compresses in the single cavity, thereby minimizing emittance increases from bunching.

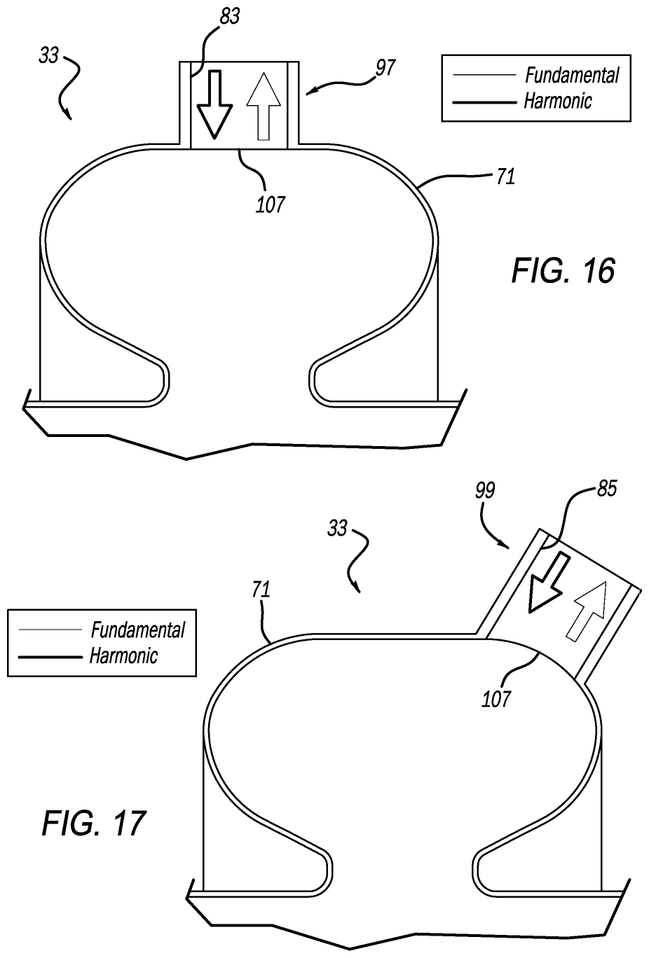

Reference should now be made to FIGS. 15-17. Maintaining synchronization between the modes, including integer or simple-fraction frequency ratios, is desirable for maintaining coherence between them and the beams transiting the cavity. More particularly, the modes should be integer multiples of one another, specifically the frequency of the TM₀₁₀ should ideally be exactly ½ of the frequency of the TM₀₁₁ mode. One or more spaced apart tuners are implemented in order to further optimize the performance of dual-mode RF cavity 33: an on-equator, radially oriented tuner 97 (see FIG. 16), and an off-equator, diagonally oriented tuner 99 (see FIG. 17).

The tuners are preferably plungers 101, such as externally threaded brass shafts, enmeshed with an internally threaded sleeve or plug 103 connected within a recess 105 of cavity body 71. Insertion or retraction of plunger 101 deforms a thin bridge 107 of cavity body 71. The plunger and bridge movement of the tuners enable independent adjustments to the resonant frequencies of the two modes within the cavity. Inserting or retracting the tuner plungers 101 alters the internal cavity volume and, thus, the mode frequencies. On-equator tuner 97, when inserted, effects a positive change in frequency of TM₀₁₁ with a concurrent negative change in frequency of TM₀₁₀. Moreover, off-equator tuner 99, on the other hand, increases the resonant frequency of both modes when inserted. The relative insertion depth of the two tuners can, within limits, be set to attain the desired integer ratio of 2 between the TM₀₁₀ and TM₀₁₁ resonant frequencies, as well as set an absolute frequency for one of the modes.

In one version, the plungers may be manually rotated for advancing and retracting. In another version, an electromagnetic actuator may be used to rotationally or linearly, automatically advance and retract each plunger. Use of the tuners 97 and 99 is an optional feature that may or may not be incorporated into the present dual-mode RF cavity system.

Cross-talk reduction will now be discussed in greater detail. The present apparatus and method operate two independent couplers in a single cavity, such that each is intended to have β=1 coupling to the desired mode and β=0 for the other driven mode. Accordingly, there should be minimal power transmitted between the couplers. Power couplers which are strongly interacting with both their own and other powered modes (i.e., cross-talk) would result in potentially significant fractions of power being uselessly transmitted between the couplers with net diminished power coupled to the cavity volume. Thus, the presently preferred coupler locations and geometries have been optimized so as to minimize the cross-talk.

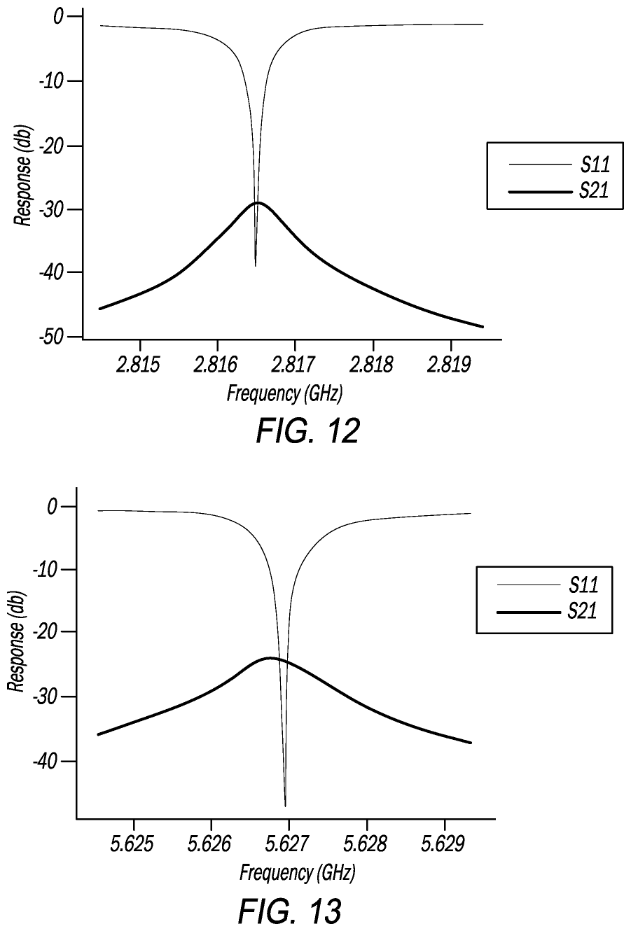

The expected results shown in FIGS. 12 and 13 highlight the low transmitted power between the couplers. When calculated from the log-scale, approximately 2% of power at f=2.81652 GHz is transmitted from the loop coupler to the electric field probe and 0.3% of power at f=5.62667 GHz is transmitted from the electric field probe to the loop coupler. Further cross-talk could likely be additionally reduced. When the loop coupler's coupling to the TM₀₁₁ mode is explored, as opposed to the designed-for fundamental mode, it is found that the coupling is dependent upon the orientation of the loop coupler. The electric field probe, intended to couple to the TM₀₁₁ mode, exhibits almost no coupling to the TM₀₁₀ mode due to the minimal electric field magnitude that mode exhibits at the cavity equator. FIG. 12 is cross-talk from the loop coupler to the electric field probe coupler, and presents expected noise response versus frequency for approximately 0.3% power transmitted, with the S11 line representing the loop coupler and the S21 line representing the electric field probe. Next, FIG. 13 is cross-talk from the electric field probe coupler to the loop coupler, and presents expected noise response versus frequency for approximately 0.2% power transmitted, with the S11 line representing the electric field probe and the S21 line representing the loop coupler.

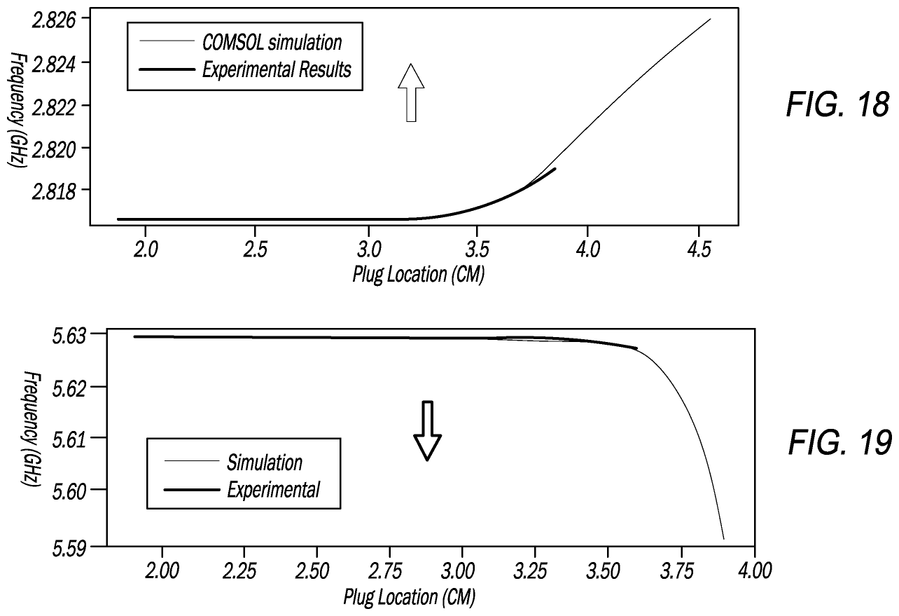

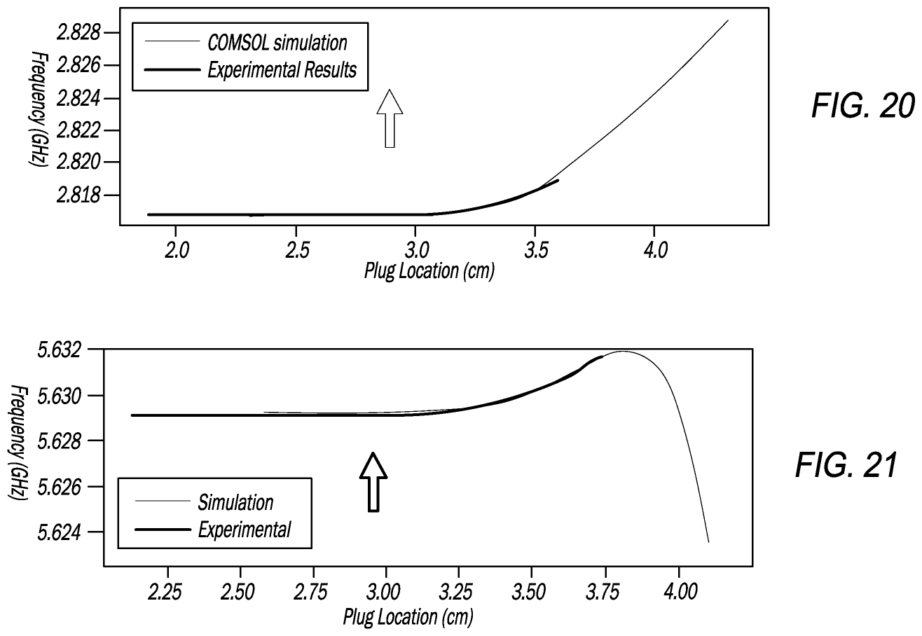

Tuner response will be considered with reference to FIGS. 18-21. The expected resonant frequencies of the TM₀₁₀ and TM₀₁₁ cavity modes are recorded as the tuners were moved in ~0.3 mm steps. The tuner plungers are initially mounted and zeroed at the flange connection for each port prior to moving them. These tests determine a tuning range accessible by these tuners: with either: (a) the tuner being pulled out of the cavity so far it no longer had any effect on the resonant frequency, or (b) the tuner inserted far enough into the cavity to detune a mode to the point of significantly altering the field pattern and/or impacting its coupling. FIGS. 18 and 19 illustrate on-equator tuner frequency changes in the fundamental mode and in the TM₀₁₁ mode, respectively. Thereafter, FIGS. 20 and 21 illustrate off-equator tuner frequency changes in the fundamental mode and in the TM₀₁₁ mode, respectively.

While various embodiments have been disclosed, other variations may be employed. For example, alternate coupler configurations and locations may be used although the results may not be as advantageous. Additional or alternate tuner constructions and locations can be employed although some advantages may not be realized. Moreover, additional or alternate RF electronics and gun arrangements may be provided, but some benefits may not be achieved. It is intended by the following claims to cover these and any other departures from the disclosed embodiments which fall within the true spirit of this invention.

The invention claimed is:

1. A radio frequency apparatus comprising:
a radio frequency cavity including a hollow body with a curved interior surface therein;
an electron entry port configured to allow electrons to enter into the body;
an electron exit port configured to allow electrons to exit the body;
an electrical field coupler having a distal end located within the body;
a magnetic field coupler having a distal end located within the body, the couplers being spaced apart from each other;
at least one radio frequency generator connected to the couplers; and
the couplers being configured to provide both an electric field and a magnetic field within the same cavity.

2. The apparatus of claim 1, wherein:
a first of the couplers is located on-axis and on-equator of the cavity; and
a second of the couplers is located off-axis and off-equator of the cavity.

3. The apparatus of claim 1, further comprising:
a radio frequency gun, driven by a laser or high-voltage extractor, emitting bunches of the electrons to the cavity; and
a spectrometer or a microscope detector obtaining a specimen image from the electrons exiting the cavity.

4. The apparatus of claim 1, further comprising a quantum bit configured to use quantum states created by the cavity, which is a superconducting cavity.

5. The apparatus of claim 1, wherein the couplers and the cavity are configured to:
use a second harmonic to linearize time-dependence of a field experienced by an electron particle transiting within the cavity; and
both accelerate and chirp an electron beam for velocity-based bunch compression while reducing or eliminating intra-cavity beam energy droop.

6. The apparatus of claim 1, wherein the couplers are configured to adjust phase and amplitude such that an incoming beam of the electrons entering the cavity is accelerated and remains on a highly linear portion of a radio frequency waveform, while reducing or eliminating deceleration of the beam while the beam transits the cavity.

7. The apparatus of claim 1, wherein:
the electrical field coupler supplies a harmonic mode within the cavity;
the magnetic field coupler supplies a fundamental mode within the cavity;
the couplers provide independent control of each mode's phase and amplitude; and
the couplers are spaced apart from each other by at least 30°.

8. The apparatus of claim 1, further comprising a tuner operably advancing or retracting to change a shape of the curved interior surface of the cavity and to change an internal volume of the cavity, which changes a radio frequency mode within the cavity.

9. The apparatus of claim 1, further comprising a radio frequency tuner mounted to the cavity, the tuner including an automatically movable plunger.

10. The apparatus of claim 1, further comprising an internal hollow shape of the cavity having a substantially ∞ or 8 shape with a cylindrical beam pipe passing through a constricted middle thereof, the electron entry and exit ports being located where the pipe intersects the cavity, and the magnetic field coupler projecting into an outer lobe of the cavity with an elongated axis of the magnetic field coupler facing toward a centerline axis of the pipe.

11. The apparatus of claim 1, wherein the electrical field coupler primarily excites only a fundamental mode and the magnetic field coupler primarily excites only a harmonic mode, and the couplers being located within the cavity to avoid a maximum field produced by each of the modes in order to minimize cross-talk between the couplers.

12. A radio frequency apparatus comprising:
a radio frequency cavity;
an electron entry port configured to allow electrons to enter into the cavity;
an electron exit port configured to allow electrons to exit the cavity;
a harmonic mode coupler having a distal end located within the cavity;
a fundamental mode coupler having a distal end located within the cavity, the couplers being spaced apart from each other;
a first of the couplers being located on-equator of the cavity;
a second of the couplers being located off-axis and off-equator of the cavity; and
the couplers being configured to provide both an electric field and a magnetic field within the same cavity.

13. The apparatus of claim 12, further comprising:
a radio frequency gun emitting bunches of the electrons to the cavity;
at least one power supply supplying radio frequency power to the couplers; and
a spectrometer or microscope camera obtaining a specimen image from the electrons exiting the cavity.

14. The apparatus of claim 12, wherein the couplers and the cavity are configured to:
use a second harmonic to linearize time-dependence of a field experienced by an electron particle transiting within the cavity; and
both accelerate and chirp an electron beam for velocity-based bunch compression while reducing or eliminating intra-cavity beam energy droop.

15. The apparatus of claim 12, wherein the couplers are configured to adjust phase and amplitude such that the incoming electrons entering the cavity are accelerated and remain on a highly linear portion of a radio frequency waveform, while reducing or eliminating deceleration of the electrons while the electrons transit the cavity.

16. The apparatus of claim 12, wherein:
the couplers provide independent control of each mode's phase and amplitude; and
the couplers are spaced apart from each other by at least 30°.

17. The apparatus of claim 12, further comprising a tuner operably advancing or retracting to change an internal shape or volume of the cavity, which changes a radio frequency mode within the cavity.

18. The apparatus of claim 12, further comprising an automatically movable radio frequency tuner mounted to the cavity.

19. The apparatus of claim 12, further comprising an internal hollow shape of the cavity having a substantially ∞ or 8 shape with a cylindrical beam pipe passing through a constricted middle thereof, the electron entry and exit ports being located where the pipe intersects the cavity, and the fundamental coupler projecting into an outer lobe of the cavity with an elongated axis of the fundamental coupler facing toward a centerline axis of the pipe.

20. A radio frequency apparatus comprising:
a radio frequency cavity;
an electron entry port configured to allow electrons to enter into the cavity;
an electron exit port configured to allow electrons to exit the cavity;
an electrical field coupler having a distal end located within the cavity;
a magnetic field coupler having a distal end located within the cavity, the couplers being spaced apart from each other; and
a radio frequency tuner operably advancing or retracting to change a shape of an interior surface of the cavity and to change an internal volume of the cavity, which changes radio frequency modes associated with the cavity.

21. The apparatus of claim 20, wherein the radio frequency tuner is mounted to a body of the cavity and includes a movable plunger with threads engaging the body of the cavity, and the interior surface of the cavity includes a thinner bridging segment that is pushed by a distal end of the plunger when the plunger is advanced.

22. The apparatus of claim 20, wherein the radio frequency tuner includes an automatically movable plunger that pushes against the interior surface of the cavity when the plunger is advanced.

23. The apparatus of claim 20, further comprising:
a second radio frequency tuner operably advancing or retracting to change a shape of an interior surface of the cavity;
one of the tuners being located on-axis, and across the cavity from and substantially co-axial with the magnetic field coupler;
another of the tuners being located off-axis, and across the cavity from and substantially co-axial with the electric field coupler
the magnetic field coupler being located on-equator of the cavity;
the electric field coupler being located off-equator of the cavity; and
the couplers being configured to provide both an electric field and a magnetic field within the same cavity.
